(19) United States
(12) Patent Application Publication
(10) Pub. No.: US 2026/0344121 A1
(43) Pub. Date: Oct. 29, 2026

(54) SEMICONDUCTOR LIGHT-EMITTING ELEMENT AND METHOD OF PRODUCING SEMICONDUCTOR LIGHT-EMITTING ELEMENT

(71) Applicant: DOWA Electronics Materials Co., Ltd., Chiyoda-ku, Tokyo (JP)

(72) Inventors: Kosuke INOUE, Akita-shi, Akita (JP); Jumpei YAMAMOTO, Akita-shi, Akita (JP)

(73) Assignee: DOWA Electronics Materials Co., Ltd., Chiyoda-ku, Tokyo (JP)

(21) Appl. No.: 19/148,001

(22) PCT Filed: Dec. 20, 2023
(86) PCT No.: PCT/JP2023/045794

§ 371 Date: Jul. 15, 2025

(30) Foreign Application Priority Data
Jan. 26, 2023 (JP) 2023-010503

(51) Int. Cl. H10H 20/824; H10H 20/01; H10H 20/812; H10H 20/814; H10H 20/82

(52) U.S. Cl. CPC H10H 20/824; H10H 20/013; H10H 20/017; H10H 20/018; H10H 20/019; H10H 20/812; H10H 20/814; H10H 20/82

(57) ABSTRACT

Provided are a semiconductor light-emitting element that has good light emission output relative to injected power compared to conventional light-emitting elements and in which a protective film can be formed without the formation of voids and a method of producing this semiconductor light-emitting element. The semiconductor light-emitting element includes a first conductivity type cladding layer, a light-emitting layer, and a second conductivity type cladding layer in stated order with the second conductivity type cladding layer as a light extraction side.

### TECHNICAL FIELD

The present disclosure relates to a semiconductor light-emitting element and a method of producing a semiconductor light-emitting element.

### BACKGROUND

III-V compound semiconductors obtained through stacking of epitaxial layers of InGaAsP, InGaAlAs, InAsSbP, etc. as disclosed in Patent Literature (PTL) 1 are used as semiconductor materials of semiconductor layers in semiconductor light-emitting elements. Through composition ratio adjustment of a light-emitting layer formed using a III-V compound semiconductor material, it is possible to adjust the light emission wavelength of a semiconductor light-emitting element over a wide range from green to infrared. For example, semiconductor light-emitting elements that are infrared-emitting with a light emission wavelength in an infrared region of wavelengths of 1,000 nm or more are widely used in applications such as sensors, gas analysis, surveillance cameras, and communications.

Moreover, PTL 2 describes an attempt to mitigate multi-peaks in a light emission spectrum through the inclusion of an n-type cladding layer, an active layer, and a p-type cladding layer in stated order in a semiconductor laminate in which a plurality of InGaAsP III-V compound semiconductor layers containing In and P are stacked and through the formation of a pattern of irregularities in the n-type cladding layer that constitutes a light extraction side.

### CITATION LIST

### Patent Literature

PTL 1: JP2021-077885A
PTL 2: JP2018-101675A

### SUMMARY

### Technical Problem

In recent years, there has been demand for further improvement of light-emission efficiency of light-emitting elements. The inventors have conducted research with the aim of improving light emission output relative to injected power in a light-emitting element. Moreover, the inventors have attempted to improve light emission output by controlling surface irregularities at a light extraction surface. The surface irregularities in PTL 2, which result in a developed interfacial area ratio (Sdr) of less than 1, are inadequate from a perspective of improving light emission output, and there is demand for further improvement of light emission output.

As a result of studies conducted with the aim of obtaining irregularities at a light extraction surface that are suitable for improving light emission output, the inventors found that there are instances in which hollowing occurs.

The term “hollowing” as used in the present disclosure refers to a state that arises when, in a situation in which surface roughening is performed through etching of the surface of a III-V compound semiconductor layer in a state in which a film or the like that blocks etching is formed on part of the surface, etching progresses not only in a perpendicular direction relative to thickness of the III-V semiconductor layer, but also progresses in a horizontal direction around the periphery of the film or the like, thereby resulting in etching below the film or the like around the periphery thereof. The inventors have newly recognized an issue that in a situation in which hollowing occurs, this acts as a cause of formation of regions (voids) where there is inadequate protective film formation when a protective film is formed at a light extraction surface by plasma CVD, sputtering, or the like, and that problems arise in practical application.

Accordingly, an object of the present disclosure is to provide a semiconductor light-emitting element that has good light emission output relative to injected power compared to conventional light-emitting elements and in which a protective film can be formed without the formation of voids, and also to provide a method of producing this semiconductor light-emitting element.

### Solution to Problem

As a result of diligent and extensive research to achieve the object set forth above, the inventors discovered that in the case of an infrared-emitting semiconductor light-emitting element having a light-emission wavelength in an infrared region of wavelengths of 1,000 nm or more, the adoption of InGaAlAs that does not include P as the composition of a cladding layer constituting a light extraction side makes it easier to obtain surface irregularities suitable for improving light emission output as compared to a case in which P is included. The inventors also discovered that a high Al composition in InGaAlAs makes it easier to obtain surface irregularities suitable for improving light emission output. However, the inventors found that the occurrence of hollowing described above becomes apparent when the Al composition is too high, and thus the inventors completed the present disclosure set forth below.

Specifically, primary configurations of the present disclosure are as follows.

(1) A semiconductor light-emitting element comprising a first conductivity type cladding layer, a light-emitting layer, and a second conductivity type cladding layer in stated order with the second conductivity type cladding layer as a light extraction side, wherein
the light-emitting layer is a III-V compound semiconductor that includes one type or two or more types among Al, Ga, and In as group III elements, includes one type or two or more types among As, Sb, and P as group V elements, and has a central emission wavelength of 1,000 nm to 1,900 nm,
the second conductivity type cladding layer has a composition of InₓGa_{y}Al_{z}As, where 0.49≤x≤0.55, 0.10≤z<0.35, and x+y+z=1, and the second conductivity type cladding layer has a light extraction surface with a developed interfacial area ratio (Sdr) of 4.0 or more.

(2) The semiconductor light-emitting element according to the foregoing (1), wherein the second conductivity type cladding layer has an Al composition ratio z of 0.15≤z≤0.30.

(3) The semiconductor light-emitting element according to the foregoing (1) or (2), wherein the light extraction surface of the second conductivity type cladding layer has an arithmetic mean height (Sa) of 0.60 μm or less and a skewness (Ssk) of 0.30 or more.

(4) The semiconductor light-emitting element according to any one of the foregoing (1) to (3), wherein a band gap of the second conductivity type cladding layer is larger than a band gap of the light-emitting layer.

(5) The semiconductor light-emitting element according to any one of the foregoing (1) to (4), wherein the second conductivity type cladding layer has a thickness of not less than 2 μm and not more than 10 μm.

(6) The semiconductor light-emitting element according to any one of the foregoing (1) to (5), wherein the light-emitting layer has a quantum well-type structure in which an InGaAlAs well layer and an InGaAlAs barrier layer are stacked alternately.

(7) The semiconductor light-emitting element according to any one of the foregoing (1) to (6), comprising an undoped spacer layer between the first conductivity type cladding layer and the light-emitting layer and between the light-emitting layer and the second conductivity type cladding layer.

(8) The semiconductor light-emitting element according to any one of the foregoing (1) to (7), comprising a supporting substrate, the first conductivity type cladding layer, the light-emitting layer, and the second conductivity type cladding layer in stated order and comprising a metal reflective layer between the supporting substrate and the first conductivity type cladding layer, wherein
a dielectric layer and a contact section that are disposed alongside each other are further included between the metal reflective layer and the first conductivity type cladding layer.

(9) A method of producing a semiconductor light-emitting element having a second conductivity type cladding layer as a light extraction side, comprising:
a semiconductor laminate formation step of sequentially forming a first conductivity type cladding layer, a light-emitting layer, and the second conductivity type cladding layer; and
a surface roughening treatment step of immersing the second conductivity type cladding layer in concentrated nitric acid to perform surface roughening and thereby adjust a developed interfacial area ratio (Sdr) of a light extraction surface of the second conductivity type cladding layer to 4.0 or more, wherein
the light-emitting layer is a III-V compound semiconductor that includes one type or two or more types among Al, Ga, and In as group III elements, includes one type or two or more types among As, Sb, and P as group V elements, and has a central emission wavelength of 1,000 nm to 1,900 nm, and
the second conductivity type cladding layer has a composition of InₓGa_{y}Al_{z}As, where 0.49≤x≤0.55, 0.10≤z<0.35, and x+y+z=1.

(10) The method of producing a semiconductor light-emitting element according to the foregoing (9), wherein the concentrated nitric acid in the surface roughening treatment step has a temperature of lower than 10 °C.

(11) The method of producing a semiconductor light-emitting element according to the foregoing (9) or (10), wherein the concentrated nitric acid in the surface roughening treatment step has a concentration of 60 wt % or more.

(12) The method of producing a semiconductor light-emitting element according to any one of the foregoing (9) to (11), wherein the second conductivity type cladding layer has an Al composition ratio z of 0.15≤z≤0.30.

(13) The method of producing a semiconductor light-emitting element according to any one of the foregoing (9) to (12), wherein surface roughening treatment is performed in the surface roughening treatment step such that the light extraction surface of the second conductivity type cladding layer has an arithmetic mean height (Sa) of 0.6 μm or less and a skewness (Ssk) of 0.3 or more.

(14) The method of producing a semiconductor light-emitting element according to any one of the foregoing (9) to (13), further comprising, after the surface roughening treatment step, a step of forming a mesa structure and a step of cutting a section removed by a mesa to perform segmentation.

(15) A method of producing a semiconductor light-emitting element comprising:
a semiconductor laminate formation step of sequentially forming an etching stop layer, a second conductivity type cladding layer, a light-emitting layer, and a first conductivity type cladding layer on a growth substrate;
a step of forming a dielectric layer and a contact section alongside each other on the first conductivity type cladding layer;
a metal reflective layer formation step of forming a metal reflective layer on the dielectric layer and the contact section;
a bonding step of bonding a supporting substrate differing from the growth substrate via the metal reflective layer;
a growth substrate removal step of removing the growth substrate to expose the etching stop layer;
a second conductivity type cladding layer exposure step of removing the etching stop layer to expose an upper surface of the second conductivity type cladding layer as a light extraction side; and
a surface roughening treatment step of, after the second conductivity type cladding layer exposure step, immersing the second conductivity type cladding layer in concentrated nitric acid to perform surface roughening and thereby adjust a developed interfacial area ratio (Sdr) of a light extraction surface of the second conductivity type cladding layer to 4.0 or more, wherein
the light-emitting layer is a III-V compound semiconductor that includes one type or two or more types among Al, Ga, and In as group III elements, includes one type or two or more types among As, Sb, and P as group V elements, and has a central emission wavelength of 1,000 nm to 1,900 nm, and
the second conductivity type cladding layer has a composition of InₓGa_{y}Al_{z}As, where 0.49≤x≤0.55, 0.10≤z<0.35, and x+y+z=1.

### Advantageous Effect

According to the present disclosure, it is possible to provide a semiconductor light-emitting element that has good light emission output relative to injected power compared to conventional light-emitting elements and in which a protective film can be formed without the formation of voids, and also to provide a method of producing this semiconductor light-emitting element.

### BRIEF DESCRIPTION OF THE DRAWINGS

In the accompanying drawings:

FIG. 1 is a schematic cross-sectional view for describing a semiconductor light-emitting element according to one embodiment of the present disclosure;

FIG. 2 is a schematic cross-sectional view in a production process of a semiconductor light-emitting element according to one embodiment of the present disclosure;

FIG. 3 is a schematic cross-sectional view in a production process of a semiconductor light-emitting element according to one embodiment of the present disclosure that continues on from FIG. 2;

FIG. 4 is a schematic cross-sectional view for describing a preferred form around a dielectric layer and a contact section in a semiconductor light-emitting element according to one embodiment of the present disclosure;

FIG. 5 is a schematic cross-sectional view in a production process of a semiconductor light-emitting element according to one embodiment of the present disclosure that continues on from FIG. 3;

FIG. 6 is a schematic cross-sectional view in a production process of a semiconductor light-emitting element according to one embodiment of the present disclosure that continues on from FIG. 4;

FIG. 7 is a schematic cross-sectional view for describing a semiconductor light-emitting element according to one embodiment of the present disclosure;

FIG. 8 is a schematic plan view illustrating a pattern of an upper surface electrode in Example 1;

FIG. 9 is a graph comparing Al composition ratio and Sa in examples and comparative examples of the present disclosure;

FIG. 10 is a graph comparing Al composition ratio and Sdr in examples and comparative examples of the present disclosure;

FIG. 11 is a graph comparing Al composition ratio and Ssk in examples and comparative examples of the present disclosure;

FIG. 12 is an electron micrograph for around a light extraction surface of a second conductivity type cladding layer in Comparative Example 1;

FIG. 13 is an electron micrograph for around a light extraction surface of a second conductivity type cladding layer in Example 1; and

FIG. 14 is an electron micrograph for around a light extraction surface of a second conductivity type cladding layer in Comparative Example 4.

### DETAILED DESCRIPTION

The following points are described in advance of describing embodiments according to the present disclosure.

### <Composition>

Firstly, when referring simply to a “III-V compound semiconductor” in the present specification, the composition thereof is expressed by a general formula: (InₐGa_{b}Al_{c}) (PₓAs_{y}Sb_{z}). The following relationships hold for the composition ratios of the various elements.

For the group III elements, c=1−a−b, 0≤a≤1, 0≤b≤1, and 0≤c≤1.

For the group V elements, z=1−x−y, 0≤x≤1, 0≤y≤1, and 0≤z≤1.

A III-V compound semiconductor layer referred to in the present disclosure includes one type or two or more types of group III elements selected from the group consisting of Al, Ga, and In and one type or two or more types of group V elements selected from the group consisting of As, Sb, and P.

When referring simply to “InGaAsP” without explicitly stating composition ratios, this is considered to indicate any compound in which a chemical composition ratio of group III element (total of In and Ga) and group V element (As and P) is 1:1 and in which a ratio of the group III elements In and Ga and a ratio of the group V elements As and P are undefined. This case is also inclusive of a case in which one or other of In and Ga is not included among the group III element and a case in which one or other of As and P is not included among the group V element. However, when InGaAsP “including at least In and P” is explicitly stated, this means that more than 0% and not more than 100% of In is included among the group III element and that more than 0% and not more than 100% of P is included among the group V element. Moreover, when referring to “InGaAs”, this means that P is not included in the above-described “InGaAsP” with the exception of P that becomes unavoidably mixed in during production. Likewise, when referring to “InGaAlAs”, this is considered to indicate any compound in which a chemical composition ratio of group III element (total of In, Ga, and Al) and group V element (As) is 1:1 and in which a ratio of the group III elements In, Ga, and Al and a ratio of the group V element As are undefined. Furthermore, when referring to “InP”, this means that Ga and As are not included in the above-described “InGaAsP” with the exception of Ga and As that are unavoidably mixed in during production. Note that the composition ratio of each component in InGaAsP, InGaAs, or the like can be measured by photoluminescence measurement, X-ray diffraction measurement, or the like. Also note that the phrase “unavoidably mixed in during production” as used here means not only unavoidable mixing in due to a production apparatus where a source gas is used, but also due to diffusion of atoms at the interfaces of layers during crystal growth or in accompaniment to subsequent heat treatment, for example.

### <Conductivity Type>

In the present specification, a layer that functions electrically as a p-type is referred to as a p-type semiconductor layer (also abbreviated as “p-type layer”), and a layer that functions electrically as an n-type is referred to as an n-type semiconductor layer (also abbreviated as “n-type layer”). On the other hand, a layer to which a specific impurity such as Si, Zn, S, Sn, Mg, or Te is not intentionally added is referred to as “undoped”. A III-V compound semiconductor layer that is undoped may contain impurities that are unavoidably mixed in during a production process. Specifically, when a layer has a low dopant concentration (for example, less than 5×10¹⁶ atoms/cm³), the layer is treated as “undoped” in the present specification. Moreover, in a case in which an impurity is not intentionally added to a III-V compound semiconductor layer, this III-V compound semiconductor layer is treated as undoped even when an unavoidable impurity (O, C, H, etc.) in a production process that accompanies decomposition of a source gas or the like is contained in a concentration of 5×10¹⁶ atoms/cm³ or more. Note that since InAs functions electrically as an n-type even when it is undoped, an undoped InAs layer and an n-type InAs layer are both InAs layers that function as an n-type. Values for impurity concentrations of Si, Zn, S, Sn, Mg, Te, and the like are taken to be values according to SIMS analysis. Also note that values for dopant concentrations are each taken to be the value for dopant concentration at the thickness direction center of that layer because values for dopant concentrations change significantly in proximity to the boundaries of semiconductor layers.

### <Film Thicknesses and Compositions of Layers>

The thickness of each layer can be calculated through cross-sectional observation of a grown layer using a transmission electron microscope (TEM). Composition ratios (solid phase ratios) of layers in the present specification are taken to be values obtained through SIMS analysis. Composition ratios (solid phase ratios) of layers of a light-emitting layer and composition ratios of spacer layers in the present specification are taken to be values obtained by implementing SIMS analysis (quadrupole type) in a thickness direction of the light-emitting layer after exposing the vicinity of an uppermost layer of the light-emitting layer through etching (from an n-layer side). Note that for SIMS analysis results, a value of the average element concentration in a half-thickness range of each layer at a central part of that layer in the thickness direction is adopted. In production, a layer having target composition ratios can be stacked by using growth conditions that are determined such as to give the target composition ratios by calculating solid phase ratios using a lattice constant according to XRD measurement and a value determined through conversion of a central emission wavelength according to photoluminescence (PL) measurement to Eg (i.e., the band gap) for a layer grown as a single film.

### <Surface Roughness Parameters>

The developed interfacial area ratio Sdr used in the present specification expresses the degree to which the developed interfacial area (surface area) of a defined region is larger than the area of the defined region. In the case of a completely flat surface, Sdr is zero. Moreover, the skewness Ssk is a value that indicates the symmetry between peaks and valleys when a mean line is taken as a center. An Ssk of zero indicates that there is vertical symmetry (normal distribution) relative to the mean line, whereas a positive Ssk indicates skewing toward a lower side (valley side) relative to the mean line, and a negative Ssk indicates skewing toward an upper side (peak side) relative to the mean line. Moreover, the arithmetic mean height Sa used in the present specification is a value that indicates surface roughness (μm). All of these indices are in accordance with ISO 25178.

Surface roughness parameters such as developed interfacial area ratio (Sdr), skewness (Ssk), and arithmetic mean height (Sa) according to surface roughness measurement can be measured using a contact probe-less profile analysis laser microscope (VK-X1000/1100 produced by Keyence Corporation). The surface roughness parameters are in accordance with ISO 25178-2:2012.

In the present specification, the above-described surface roughness parameters were measured as follows. Specifically, with respect to 9 arbitrary locations on a rough surface after a surface roughening treatment step, a profile analysis laser microscope (VK-X1000/1100 produced by Keyence Corporation) was used to measure the surface roughness of the surface and calculate an average value of the surface roughness. The measurement conditions were as follows.
Lens magnification: ×50
Number of pixels: 2048×1536
Gaussian filter used (S-filter: 0.5 μm)

Specific input parameters for the surface roughness measurement apparatus were as follows.
Sxp: p=2.5%
Vvv: p=80.0%
Vvc: p=10.0%, q=80.0%
Vmp: p=10.0%
Vmc: p=10.0%, q=80.0%

Surface roughness parameters Sa (arithmetic mean height), Sz (maximum height), Sq (root mean square height), Sdr (developed interfacial area ratio), Spc (arithmetic mean peak curve), Sdr (hybrid parameter), Ssk (skewness), and Sku (kurtosis) are automatically calculated in accordance with ISO 25178-2:2012.

The following provides a detailed illustrative description of embodiments of the present disclosure with reference to the drawings. Note that constituent elements that are the same are, as a rule, allotted the same reference numbers, and repeated description thereof is omitted. Also note that in the drawings, ratios of the height and width of a substrate and each layer are illustrated in a manner that is exaggerated relative to the actual ratios thereof in order to facilitate description.

### (Semiconductor Light-Emitting Element)

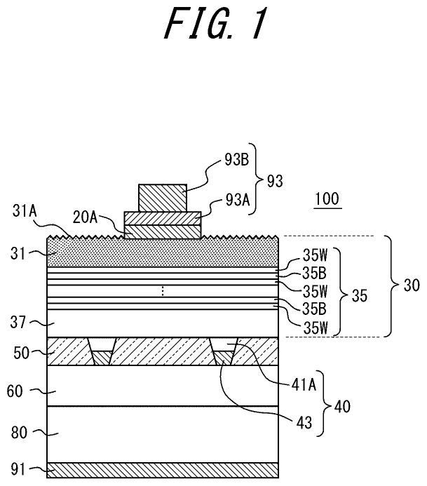

One example of an embodiment of a semiconductor light-emitting element 100 according to the present disclosure is described with reference to FIG. 1. The semiconductor light-emitting element 100 is a semiconductor light-emitting element that includes a first conductivity type cladding layer 37, a light-emitting layer 35, and a second conductivity type cladding layer 31 in stated order with the second conductivity type cladding layer 31 as a light extraction side. The light-emitting layer 35 is a III-V compound semiconductor that includes one type or two or more types among Al, Ga, and In as group III elements, includes one type or two or more types among As, Sb, and P as group V elements, and has a central emission wavelength of 1,000 nm to 1,900 nm, the second conductivity type cladding layer 31 has a composition of InₓGa_{y}Al_{z}As (0.49≤x≤0.55, 0.10≤z<0.35, x+y+z=1), and the second conductivity type cladding layer 31 has a light extraction surface 31A with a developed interfacial area ratio (Sdr) of 4.0 or more.

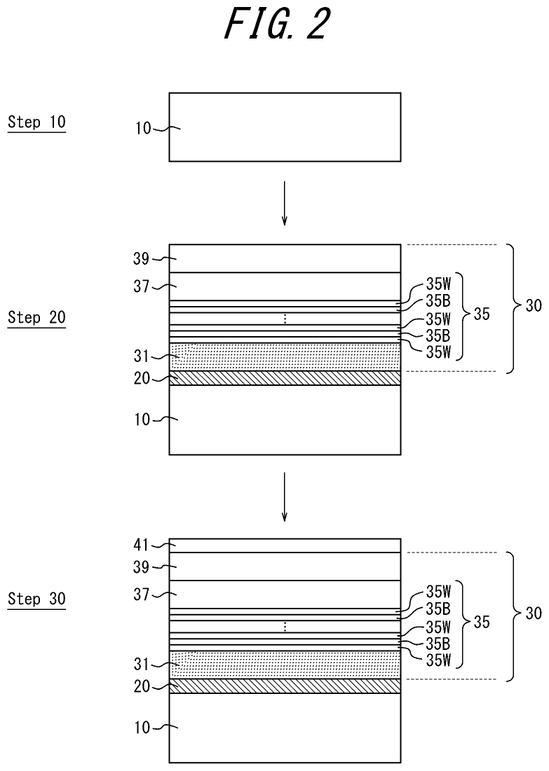

Each configuration is described below and is also described in more detail in description of an embodiment of a production method further below. Note that in the present embodiment, a case in which a bonding technique is adopted is described as an example. In a case in which a subsequently described bonding technique is adopted in the production method, a substrate that is included in the light-emitting element 100 is a supporting substrate 80. In a case in which a bonding method is not adopted, the substrate included in the light-emitting element 100 can be a growth substrate 10 (subsequently described referring to FIG. 2, etc.) that is for epitaxial growth of each semiconductor layer.

### <First Conductivity Type Cladding Layer>

The composition of the first conductivity type cladding layer 37 can be set as a commonly known composition without any specific limitations. The first conductivity type cladding layer 37 can be a III-V compound semiconductor of InGaAlAs or of InGaAsP including at least In and P, and should be a layer that has a small degree of lattice mismatch with the subsequently described light-emitting layer and that is transparent with respect to the central emission wavelength. In particular, the first conductivity type cladding layer 37 is preferably a III-V compound semiconductor of InGaAsP including at least In and P, and may be InP, for example.

### <Light-Emitting Layer>

The light-emitting layer preferably has a quantum well-type structure in which an InGaAlAs well layer 35W and an InGaAlAs barrier layer 35B are stacked alternately. Such a structure is referred to as a multiple quantum well (MQW) structure, and the inclusion of a multiple quantum well structure can improve light emission output by inhibiting crystal defects. The central emission wavelength of the semiconductor light-emitting element 100 can be set as 1,000 nm to 1,900 nm by altering the composition of the light-emitting layer. Note that in the case of a quantum well structure, it is also preferable to adjust the compositional difference between the well layer 35W and the barrier layer 35B and to impart strain to the well layer 35W in addition to altering the composition.

### <Al Composition Ratio of Second Conductivity Type Cladding Layer>

According to experiments conducted by the inventors, hollowing was confirmed to occur in a situation in which the second conductivity type cladding layer 31 has a high Al composition ratio. As also demonstrated in the subsequently described comparative examples, hollowing occurs when surface roughening of the second conductivity type cladding layer 31 is performed in a situation in which the Al composition ratio is 0.35 or more, for example. On the other hand, in a situation in which the second conductivity type cladding layer 31 has a low Al composition ratio, the composition approaches a composition that absorbs light of a desired central emission wavelength of 1,100 nm to 1,900 nm, which is within the scope of the present disclosure, and this acts as a cause of reduction of light emission output of the semiconductor light-emitting element. From these viewpoints, the composition of the second conductivity type cladding layer 31 is required to satisfy InₓGayAlzAs (0.49≤x≤0.55, 0.10≤z<0.35, x+y+z=1). In particular, it is preferable that the Al composition ratio z satisfies 0.15≤z≤0.30, and more preferable that the Al composition ratio z satisfies 0.20≤z≤0.30.

The term “hollowing” used above refers to a state that arises when, in a situation in which surface roughening is performed through etching of the surface of a III-V compound semiconductor layer in a state in which a film or the like that blocks etching is formed on part of the surface, etching progresses not only in a perpendicular direction relative to thickness of the III-V semiconductor layer, but also progresses in a horizontal direction around the periphery of the film or the like, thereby resulting in etching below the film or the like around the periphery thereof. For example, this refers to a state in which upon observation of a cross-section of surface irregularities, corrosion or caves in a horizontal direction relative to thickness that extend beyond a boundary line between a region where surface roughening is performed and a region where surface roughening does not occur due to a film or the like blocking etching are observed directly below the region where surface roughening does not occur. Hollowing such as described above occurs during etching in a surface roughening treatment step as described above. Moreover, in a subsequently described step of forming a protective film of SiO₂ or the like after the surface roughening treatment step, the hollowing acts as a cause of formation of an imperfect protective film having sections (also referred to as voids) where the protective film and the surface of the second conductivity type cladding layer 31 (light extraction surface) are not in contact, and it may not be possible to achieve energized life characteristics at a stage at which a semiconductor light-emitting element that can finally be incorporated into a device is obtained. Besides the above, hollowing may also act as a cause of inadequate application or removal of a resist.

### <Surface Irregularities of Light Extraction Surface of Second Conductivity Type Cladding Layer>

In the semiconductor light-emitting element 100 in FIG. 1, light radiating from the light-emitting layer 35 passes through the surface of the second conductivity type cladding layer 31 at a section where an electrode or the like is not formed and is externally emitted. Note that the term “light extraction side” as used in the present specification refers to a side at which light radiating from the light-emitting layer 35 is externally emitted in the semiconductor light-emitting element 100 and that the second conductivity type cladding layer 31 is taken to be the “light extraction side” in the present embodiment. Moreover, the term “light extraction surface” refers to a surface where an electrode or the like is not formed at an upper surface of the second conductivity type cladding layer 31 constituting the “light extraction side”. In the semiconductor light-emitting element 100, the light extraction surface 31A of the second conductivity type cladding layer 31 has a developed interfacial area ratio (Sdr) of 4.0 or more as a result of undergoing surface roughening treatment. In a situation in which Sdr of the light extraction surface 31A of the second conductivity type cladding layer 31 is less than 4.0, it is not possible to achieve sufficient light emission output in this semiconductor light-emitting element. The developed interfacial area ratio (Sdr) is preferably 4.4 or more. Sdr is preferably 7.0 or less, and is more preferably 5.8 or less in order to reliably avoid the occurrence of hollowing described above at the surface that has undergone surface roughening. Moreover, it is preferable that the light extraction surface 31A of the second conductivity type cladding layer 31 has an arithmetic mean height (Sa) of 0.60 μm or less and a skewness (Ssk) of 0.30 or more, and more preferable that Sa is 0.55 μm or less and Ssk is 0.40 or more. Through a small arithmetic mean height (Sa) such as 0.60 μm or less, it is possible to increase close adherence with a protective film. Note that a side surface of the second conductivity type cladding layer 31 may or may not be subjected to surface roughening.

### <Band Gap of Second Conductivity Type Cladding Layer>

For the same reasons, it is preferable that the second conductivity type cladding layer 31 does not absorb light from the light-emitting layer, and thus, more directly, it is preferable that a band gap of the second conductivity type cladding layer 31 is larger than a band gap of the light-emitting layer 35. The band gap of the second conductivity type cladding layer 31 can be estimated from the composition thereof, and the band gap of the light-emitting layer 35 can be measured through PL measurement.

### <Thickness of Second Conductivity Type Cladding Layer>

The thickness of the second conductivity type cladding layer 31 is preferably at least a certain thickness in consideration that surface roughening is performed, but conversely, excessive thickness increases production cost. Therefore, the thickness of the second conductivity type cladding layer 31 is preferably not less than 2 μm and not more than 10 μm.

Note that in a case in which the conductivity type of the first conductivity type cladding layer 37 is an n-type, the second conductivity type cladding layer 31 is a p-type. Conversely, in a case in which the conductivity type of the first conductivity type cladding layer 37 is a p-type, the second conductivity type cladding layer 31 is an n-type.

### <Spacer Layer, Metal Reflective Layer, Dielectric Layer, and Contact Section (Contact Layer and Ohmic Metal Section)>

An undoped spacer layer may be included between the first conductivity type cladding layer 37 and the light-emitting layer 35 and between the light-emitting layer 35 and the second conductivity type cladding layer 31. Also, a metal reflective layer 60 may be included between the supporting substrate 80 and the first conductivity type cladding layer 37, and a dielectric layer 50 and a contact section 40 that are disposed alongside each other may be further included between the metal reflective layer 60 and the first conductivity type cladding layer 37. Moreover, the contact section 40 can include a contact region 41A that is formed of part of a contact layer 41 and an ohmic metal section 43 and can have the ohmic metal section 43 at the surface of the contact region 41A.

### <Upper Surface Electrode and Rear Surface Electrode>

The semiconductor light-emitting element 100 may have an upper surface electrode 93 including a wiring section 93A and a pad section 93B formed on the second conductivity type cladding layer 31, and may further have a rear surface electrode 91 formed at a rear surface of the supporting substrate 80.

### (Method of Producing Semiconductor Light-Emitting Element)

In a method of producing a semiconductor light-emitting element according to the present disclosure, a second conductivity type cladding layer is taken to be a light extraction side. This production method includes a semiconductor laminate formation step of sequentially forming a first conductivity type cladding layer, a light-emitting layer, and a second conductivity type cladding layer and a surface roughening treatment step of immersing the second conductivity type cladding layer in concentrated nitric acid to perform surface roughening and thereby adjust a developed interfacial area ratio (Sdr) of a light extraction surface of the second conductivity type cladding layer to 4.0 or more. The light-emitting layer is a III-V compound semiconductor that includes one type or two or more types among Al, Ga, and In as group III elements, includes one type or two or more types among As, Sb, and P as group V elements, and has a central emission wavelength of 1,000 nm to 1,900 nm, and the second conductivity type cladding layer has a composition of InₓGa_{y}Al_{z}As (0.49≤x≤0.55, 0.10≤z<0.35, x+y+z=1).

Next, an example of a method of producing a semiconductor light-emitting element according to one embodiment of the present disclosure is described with reference to FIGS. 2 to 7. In the present embodiment, a case in which a bonding technique is adopted is described as an example. The method of producing a semiconductor light-emitting element can include a semiconductor laminate formation step, a metal reflective layer formation step, a bonding step, a growth substrate removal step, a second conductivity type cladding layer exposure step, and a surface roughening treatment step. Details of these steps are described sequentially below.

### <Semiconductor Laminate Formation Step>

As illustrated in FIG. 2, in the semiconductor laminate formation step, an etching stop layer 20, a second conductivity type cladding layer 31, a light-emitting layer 35, and a first conductivity type cladding layer 37 are sequentially formed on a growth substrate 10 to form a semiconductor laminate 30. The light-emitting layer is a III-V compound semiconductor that includes one type or two or more types among Al, Ga, and In as group III elements, includes one type or two or more types among As, Sb, and P as group V elements, and has a central emission wavelength of 1,000 nm to 1,900 nm, the second conductivity type cladding layer 31 has a composition of InₓGa_{y}Al_{z}As (0.49≤x≤0.55, 0.10≤z<0.35, x+y+z=1), and the Al composition ratio z is preferably 0.15≤z≤0.30. The following describes details of this step.

First, in the semiconductor laminate formation step, a growth substrate 10 is prepared as illustrated in Step 10 in FIG. 2. In the present embodiment, it is preferable to use an InP substrate as the growth substrate 10 since a p-type cladding layer is formed as a first conductivity type cladding layer 37 and an n-type cladding layer is formed as a second conductivity type cladding layer 31. Note that a generally available n-type InP substrate, high-resistance (also referred to as semi-insulating) InP substrate (for example, doped with Fe and having a specific resistance of 1×10⁶ Ω·cm or more), or p-type InP substrate can be used as the InP substrate. For convenience of description, the following provides an illustrative description of a case in which an n-type InP substrate is used as the growth substrate 10. Therefore, in the embodiment described below, the first conductivity type cladding layer 37 may be referred to simply as a p-type cladding layer 37, and the second conductivity type cladding layer 31 may be referred to simply as an n-type cladding layer 31.

Next, an etching stop layer 20 is formed on the growth substrate 10 as illustrated in Step 20 in FIG. 2. The etching stop layer 20 should have etching selectivity with respect to the growth substrate 10. InGaAs is adopted as the etching stop layer 20 in the present disclosure. This etching stop layer 20 can be used in removal of the growth substrate 10 by etching in the growth substrate removal step. In order to achieve lattice matching between the n-type InP substrate and InGaAs, it is preferable to use InGaAs in which the In composition ratio among group III elements is set as 0.3 to 0.7, and more preferable to use InGaAs in which this In composition ratio is set as 0.5 to 0.6.

Next, an n-type cladding layer 31, a light-emitting layer 35, and a p-type cladding layer 37 are sequentially formed on the etching stop layer 20 to form a semiconductor laminate 30. The semiconductor laminate 30 can have a double hetero (DH) structure or a multiple quantum well (MQW) structure in which the light-emitting layer 35 is sandwiched between the p-type cladding layer 37 and the n-type cladding layer 31. In order to improve light output through inhibition of crystal defects, it is more preferable that the light-emitting layer 35 has a multiple quantum well structure. The multiple quantum well structure can be formed through a structure in which a well layer 35W and a barrier layer 35B are repeated alternately. The well layer 35W and the barrier layer 35B include one type or two or more types among Al, Ga, and In as group III elements and include one type or two or more types among As, Sb, and P as group V elements. It is more preferable that one type of group V element is included. For example, the well layer 35W can be set as InGaAlAs and the barrier layer 35B can be set as InGaAlAs having a larger band gap than the well layer 35W. The central emission wavelength can be set as from 800 nm to 1,650 nm by altering the composition of the well layer 35W. In the case of an MQW structure, the central emission wavelength can also be set as from 1,100 nm to 1,900 nm by, in addition to altering the composition, adjusting the composition difference between the well layer and the barrier layer and imparting strain to the well layer. In other words, the light-emitting layer 35 can be designed such as to have a central emission wavelength within a range of 800 nm to 1,900 nm. The central emission wavelength is preferably set as 1,000 nm to 1,900 nm. Moreover, when the composition of components in the well layer 35W is expressed as In_{xw}Ga_{yw}Al_{zw}As, the composition should be selected as appropriate from ranges of 0.50≤xw≤0.70, 0.00≤yw≤0.50, and 0.00≤zw≤0.50. Likewise, when the composition of components in the barrier layer 35B is expressed as In_{xb}Ga_{yb}Al_{zb}As, the composition should be selected as appropriate from ranges of 0.40≤xb≤0.60, 0.00≤yb≤0.60, and 0.00≤ zb≤0.60.

Although no limitations are placed on the thickness of the overall semiconductor laminate 30, the thickness can be set as 2.4 μm to 15 μm, for example. Moreover, although no limitations are placed on the thickness of the p-type cladding layer 37, the thickness can be set as 0.4 μm to 5 μm, for example. The thickness of the n-type cladding layer 31 can be set as 2 μm to 10 μm in consideration that the n-type cladding layer 31 is subjected to surface roughening as a second conductivity type cladding layer 31 at a light extraction side. In a case in which the light-emitting layer 35 has a quantum well structure, the thickness of the well layer 35W can be set as 3 nm to 15 nm, the thickness of the barrier layer 35B can be set as 5 nm to 15 nm, and the number of pairs of both of these layers can be set as 1 to 50.

In addition, it is also preferable for the semiconductor laminate 30 to include a p-type cap layer 39 formed of InGaAsP including at least In and P on the p-type cladding layer 37. Through provision of the p-type cap layer 39, lattice mismatch can be eased. Although no limitations are placed on the thickness of the p-type cap layer 39, the thickness can be set as 50 nm to 200 nm, for example. In the embodiment described below, an outermost layer of the semiconductor laminate 30 is set as the p-type cap layer 39 for convenience of description, but the p-type cap layer 39 is an optional configuration, and thus the outermost layer of the semiconductor laminate 30 may be set as the p-type cladding layer 37, for example.

Note that it is also preferable for the semiconductor laminate 30 to include an i-type InGaAlAs spacer layer and an i-type InP spacer layer between the n-type cladding layer 31 and the light-emitting layer 35 and between the light-emitting layer 35 and the p-type cladding layer 37, though this is not illustrated in the drawings. The provision of spacer layers can prevent dopant diffusion. Although no limitations are placed on the thickness of the spacer layers, the thickness can be set as 50 nm to 400 nm, for example. Moreover, the semiconductor laminate 30 may include window layers between the n-type and p-type cladding layers and the spacer layers. The window layers may have the same compositions as the cladding layers or may have compositions in which the dopant concentration is changed in order to cause efficient injection of carriers into an active layer.

Each layer of the semiconductor laminate 30 can be formed by epitaxial growth. For example, each layer can be formed by a commonly known thin film growth method such as metal organic chemical vapor deposition (MOCVD), molecular beam epitaxy (MBE), or sputtering. For example, trimethylindium (TMIn) as an In source, trimethylgallium (TMGa) as a Ga source, arsine (AsH₃) as an As source, and phosphine (PH₃) as a P source can be used in a specific mixing ratio, and these source gases can be used to perform vapor phase growth while also using a carrier gas to thereby enable formation of a semiconductor layer of desired thickness in accordance with the growth time. Note that in a case in which a layer is to be doped as a p-type or an n-type, a dopant source gas should also be used as desired.

In one example of the present embodiment of the production method, a contact section formation step and a dielectric layer formation step are included following on from the semiconductor laminate formation step. These steps are described below.

### <<Contact Section Formation Step>>

In the contact section formation step, a contact layer 41 formed of a III-V compound semiconductor is first formed on the semiconductor laminate 30. For example, a p-type contact layer 41 can be formed on the p-type cap layer 39 as illustrated in Step 30 in FIG. 2. The p-type contact layer 41 is a layer that is in contact with ohmic metal sections 43 and that is interposed between the ohmic metal sections 43 and the semiconductor laminate 30. The p-type contact layer 41 should have a composition resulting in reduced contact resistance with the ohmic metal sections 43 as compared to the semiconductor laminate 30 and can be a p-type InGaAs layer, for example. Although no limitations are placed on the thickness of the contact layer 41, the thickness can be set as 50 nm to 200 nm, for example.

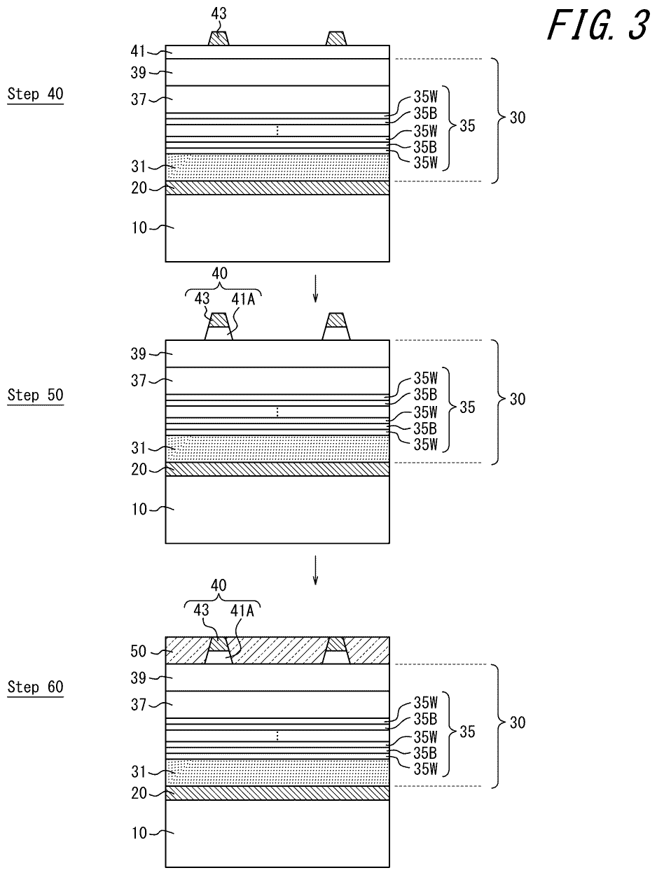

Next, ohmic metal sections 43 are formed on part of the contact layer 41 such that an exposed region remains at the surface of the contact layer 41 as illustrated in Step 40 in FIG. 3. The ohmic metal sections 43 can be formed with dispersed island shapes in a specific pattern. In a case in which a p-type InGaAs layer is adopted as the p-type contact layer 41, Au, AuZn, AuBe, AuTi, or the like, for example, can be used as the ohmic metal sections 43. The use of a layered structure of these metals is also preferable. For example, Au/AuZn/Au can be used as the ohmic metal sections 43. Although no limitations are placed on the thickness (or total thickness) of the ohmic metal sections 43, the thickness can be set as 300 nm to 1,300 nm, and more preferably as 350 nm to 800 nm, for example.

An exposed region can be left at the surface of the contact layer 41 by, for example, forming a resist pattern on the surface of the contact layer 41, performing vapor deposition of the ohmic metal sections 43, and then performing lift-off of the resist pattern to form the ohmic metal sections 43. Alternatively, the ohmic metal sections 43 may be formed by forming a specific metal layer over the entire surface of the contact layer 41, forming a mask on the metal layer, and then performing etching or the like. In either case, the ohmic metal sections 43 are formed on part of the contact layer 41, and a surface that is not in contact with the ohmic metal sections 43 (i.e., an exposed region) can be formed at the surface of the contact layer 41 as illustrated in Step 40 in FIG. 3.

It should be noted that although the ohmic metal sections 43 may have a trapezoidal shape in a cross-sectional view as illustrated in Step 40 in FIG. 3, this is merely a schematic illustration of the shape of the ohmic metal sections 43. The ohmic metal sections 43 may be formed with a rectangular shape in a cross-sectional view, and may have a shape with rounded corners.

In addition, in the contact section formation step, the contact layer 41 is removed in the exposed region up until the surface of the semiconductor laminate 30 is exposed, thereby forming contact sections 40 that are each formed of an ohmic metal section 43 and a contact region 41A as illustrated in Step S50 in FIG. 3. In other words, the contact layer 41 is etched until the surface of the p-type cap layer 39, which is an outermost layer of the semiconductor laminate 30, is exposed at locations other than where the ohmic metal sections 43 have previously been formed, and thus the contact layer 41 becomes contact regions 41A. For example, a resist mask may be formed on the ohmic metal sections 43 and in proximity thereto (approximately 2 μm to 5 μm), and then the exposed region of the contact layer 41 may be wet etched using a tartaric acid-hydrogen peroxide etchant or the like. The wet etching can alternatively be performed using an inorganic acid-hydrogen peroxide etchant, an organic acid-hydrogen peroxide etchant, or the like. Moreover, in a case in which the ohmic metal sections 43 have been formed through formation of a mask on a specific metal layer and subsequent etching in formation of the exposed region, etching may be performed continuously.

Note that the thickness of each of the contact sections 40 corresponds to the total thickness of the contact layer 41 (contact region 41A) and the ohmic metal section 43 and can be set as 350 nm to 1,500 nm, and more preferably as 400 nm to 1,000 nm.

### <<Dielectric Layer Formation Step>>

In the dielectric layer formation step, a dielectric layer 50 is formed on at least part of the cap layer 39 of the semiconductor laminate 30 as illustrated in Step S60 in FIG. 3. Such a dielectric layer 50 can be formed as described below, for example.

First, a dielectric layer is deposited over the entire surface of the semiconductor laminate 30 such as to cover the semiconductor laminate 30 and the contact sections 40. A commonly known technique such as plasma CVD or sputtering can be adopted as the deposition method. In a situation in which a dielectric is formed on the contact sections 40 in the dielectric layer 50 at the surface of the deposited dielectric layer above the contact sections 40, the dielectric on the contact sections 40 may be removed by forming a mask and performing etching or the like as desired. For example, the dielectric on the contact sections 40 can be wet etched using buffered hydrofluoric acid (BHF) or the like.

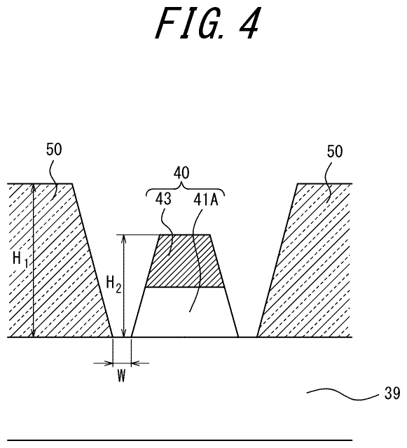

Note that it is also preferable to form the dielectric layer 50 on part of the cap layer 39 of the semiconductor laminate 30 and to set surrounding regions of the contact sections 40 as exposed sections as illustrated in FIG. 4. Such a dielectric layer 50 and exposed sections can be formed as described below, for example. First, a dielectric layer is deposited over the entire surface of the semiconductor laminate 30, and then a window pattern completely surrounding the contact sections 40 is formed by a resist above the contact sections 40 at the surface of the deposited dielectric layer. In this situation, it is preferable that the window pattern is widened by approximately 1 μm to 5 μm relative to the width direction and longitudinal direction lengths of the contact sections 40. By using a resist pattern that has been formed in this manner to etch and thereby remove dielectric in proximity to the contact sections 40, a dielectric layer 50 is formed, and surrounding areas of the contact sections 40 become exposed sections.

In order to reliably obtain this shape, the width W of the exposed sections is preferably set as not less than 0.5 μm and not more than 5 μm, and is more preferably set as not less than 1 μm and not more than 3.5 μm.

It is also preferable that a contact area ratio of contact of the dielectric layer 50 with the semiconductor laminate 30 is set as not less than 80% and not more than 95%. This is because decreasing the area of the contact sections 40 and increasing the area of the dielectric layer 50 makes it possible to inhibit light absorption by the contact sections 40. Note that the contact area ratio can be measured while in the form of a wafer or can be measured after segmentation.

Although no specific limitations are placed on the relationship between the thickness H₁ of the dielectric layer 50 that is formed in the dielectric layer formation step and the thickness H₂ of the contact sections 40, when the thickness of the dielectric layer 50 is taken to be H₁ and the thickness of the contact sections 40 is taken to be H₂, these thicknesses can be set as H₁≥H₂, and it is also preferable to set the thicknesses as H₁>H₂ as illustrated in FIG. 4. Under this condition, the thickness of the dielectric layer 50 can be set as 360 nm to 1,600 nm, and more preferably as 410 nm to 1,100 nm, for example. Moreover, it is also preferable for the difference H₁-H₂ between the thickness H₁ of the dielectric layer 50 and the thickness H₂ of the contact sections 40 to be set as not less than 10 nm and not more than 100 nm.

SiO₂, SiN, ITO, AlN, or the like can be used as the dielectric layer 50. In particular, it is preferable that the dielectric layer 50 is formed of SiO₂. This is because SiO₂ is easy to process by etching using BHF or the like.

### <Metal Reflective Layer Formation Step>

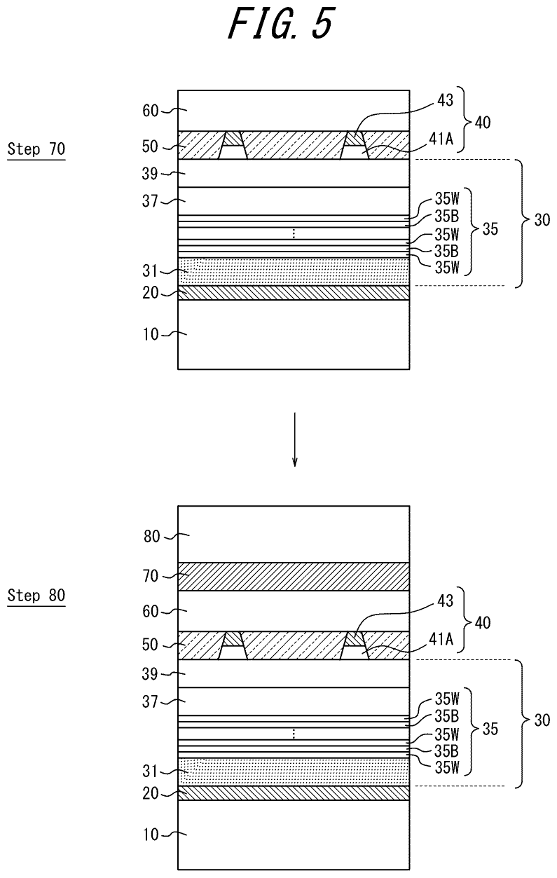

In the metal reflective layer formation step, a metal reflective layer 60 that reflects light radiating from the light-emitting layer 35 is formed on the dielectric layer 50 and the contact sections 40 that are disposed alongside one another as illustrated in Step 70 in FIG. 5. Note that in a case in which exposed sections have been formed in the dielectric layer formation step, the metal reflective layer 60 is also formed on the exposed sections. Au, Al, Pt, Ti, Ag, or the like can be used in the metal reflective layer 60, and it is particularly preferable that Au is a main component of the metal reflective layer 60. In this case, Au preferably constitutes more than 50 mass % in the composition of the metal reflective layer 60, and more preferably constitutes 80 mass % or more in the composition of the metal reflective layer 60. Although the metal reflective layer 60 can include a plurality of metal layers, in a case in which the metal reflective layer 60 includes a metal layer formed of Au (hereinafter, referred to as a “Au metal layer”), it is preferable that the thickness of the Au metal layer constitutes more than 50% of the total thickness of the metal reflective layer 60. For example, the metal reflective layer may be a single layer that is formed of only Au, or two or more Au metal layers may be included in the metal reflective layer. In order to reliably perform bonding in the subsequent bonding step, it is preferable that an outermost layer of the metal reflective layer (i.e., a surface at the opposite side to the semiconductor laminate 30) is set as a Au metal layer. For example, metal layers of Al, Au, Pt, and Au can be deposited in order on the dielectric layer 50, the exposed sections, and the contact sections 40, and these metal layers can constitute the metal reflective layer. The thickness of one Au metal layer in the metal reflective layer can be set as 400 nm to 2,000 nm, for example, and the thickness of a metal layer formed of a metal other than Au in the metal reflective layer can be set as 5 nm to 200 nm, for example. The metal reflective layer 60 can be deposited and formed on the dielectric layer 50, the exposed sections, and the contact sections 40 by a typical technique such as vapor deposition.

### <Bonding Step>

In the bonding step, a supporting substrate 80 differing from the growth substrate 10 is bonded via the metal reflective layer 60 as illustrated in Step 80 in FIG. 5. A metal bonding layer 70 may be formed at the surface of the supporting substrate 80 in advance by sputtering, vapor deposition, or the like. This metal bonding layer 70 and the metal reflective layer 60 can be bonded to each other by arranging the metal bonding layer 70 and the metal reflective layer 60 in opposition to each other and then performing hot compression bonding at a temperature of approximately 250 °C to 500 °C.

A metal such as Ti, Pt, or Au or a metal (Sn, etc.) that forms a eutectic alloy with gold can be used in the metal bonding layer 70 that is bonded to the metal reflective layer 60, and a layer in which these metals are stacked is preferable. For example, a layer obtained by stacking Ti with a thickness of 400 nm to 800 nm, Pt with a thickness of 5 nm to 20 nm, and Au with a thickness of 700 nm to 1,200 nm in order from the surface of the supporting substrate 80 can be adopted as the metal bonding layer 70. Note that in order to facilitate bonding of the metal reflective layer 60 and the metal bonding layer 70, it is preferable that a Au metal layer is adopted as an outermost layer at the metal bonding layer 70 side, that Au is also adopted as a metal layer at the metal bonding layer 70 side of the metal reflective layer 60, and that bonding is performed between Au through Au-Au diffusion.

Note that a conductive Si substrate can be used as the supporting substrate 80, for example. Alternatively, a conductive GaAs substrate or Ge substrate may be used. Moreover, besides a semiconductor substrate such as described above, it is also possible to use a metal substrate or to use a submount substrate in which a heat-dissipating insulating substrate of fired AlN or the like is used.

### <Growth Substrate Removal Step>

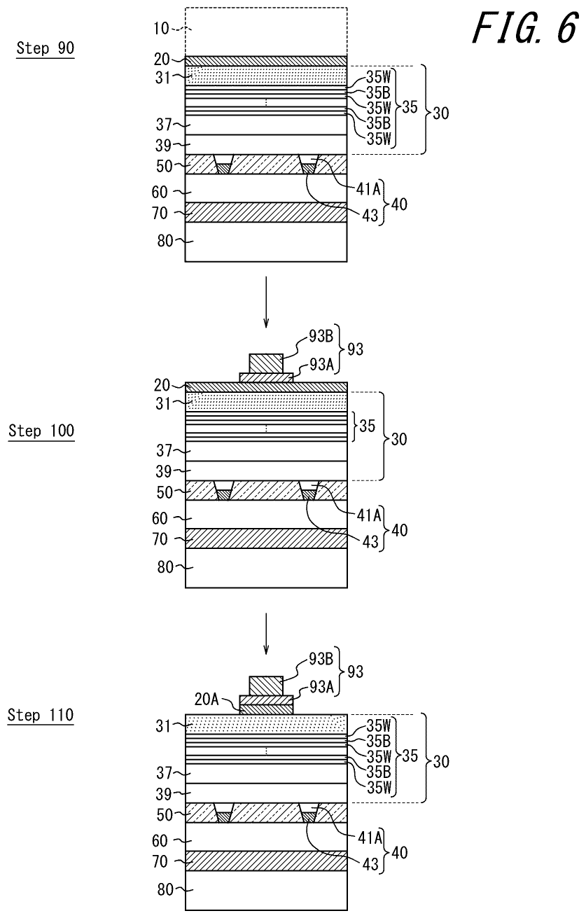

In the growth substrate removal step, the growth substrate 10 is removed to expose the etching stop layer 20 as illustrated in Step 90 in FIG. 6. The growth substrate 10 can be removed through wet etching using dilute hydrochloric acid, for example, and the etching stop layer 20 can serve as an end point of the wet etching.

### <Second Conductivity Type Cladding Layer Exposure Step>

In the second conductivity type cladding layer exposure step, an n-side electrode 93 is formed as an upper surface electrode on an n-side electrode formation region 20A of the etching stop layer 20 that has been exposed while also partially removing the etching stop layer 20 as illustrated in Step 100 and Step 110 in FIG. 6. This can provide the semiconductor laminate 30 with a light extraction surface 31A. The etching stop layer 20 may be partially removed after the n-side electrode 93 has been provided on the n-side electrode formation region 20A, or the etching stop layer 20 may be removed in advance with the exception of in the n-side electrode formation region 20A, and the n-side electrode 93 may subsequently be formed. The etching stop layer 20 can be removed through wet etching using a sulfuric acid-hydrogen peroxide etchant or a tartaric acid-hydrogen peroxide etchant.

Note that the etching stop layer 20 on the second conductivity type cladding layer 31 at the light extraction surface 31A can alternatively be etched in the subsequently described surface roughening treatment step, and thus removal of the etching stop layer 20 can be performed concurrently in surface roughening treatment. Accordingly, a step of removing the etching stop layer 20 described above can be omitted, and it is also preferable to use the etching stop layer 20 as a mask to delay the start of etching of the second conductivity type cladding layer 31 and to control the shape of surface irregularities of the second conductivity type cladding layer 31 at the light extraction surface 31A.

### <Surface Roughening Treatment Step>

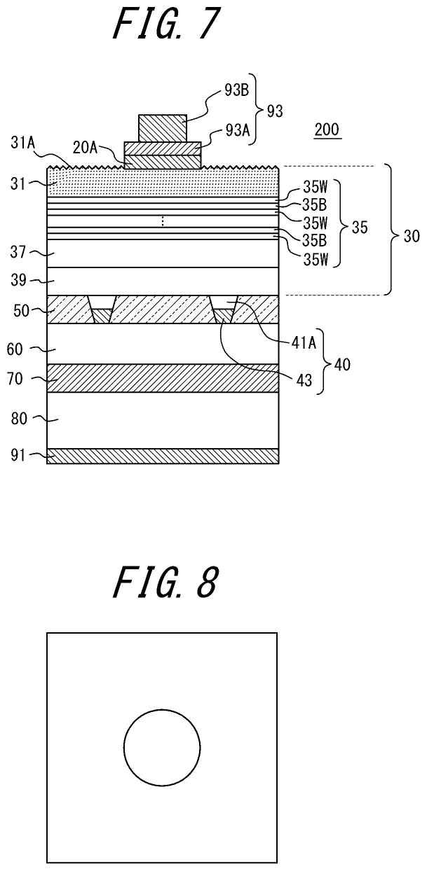

In the subsequent surface roughening treatment step, the second conductivity type cladding layer 31 that has been exposed, with the exception of the n-side electrode 93, is immersed in concentrated nitric acid to perform surface roughening and thereby adjust a developed interfacial area ratio (Sdr) of the light extraction surface 31A of the second conductivity type cladding layer 31 to 4.0 or more. The concentrated nitric acid used in the surface roughening treatment can be an etchant that has been prepared with a concentration of 61 wt % or can be a commercially available etchant such as electronics industry nitric acid (produced by Kanto Chemical Co., Inc.; Nitric acid 1.38). Moreover, Sdr is preferably adjusted to 4.4 or more. Furthermore, Sdr is preferably adjusted to 7.0 or less, and more preferably adjusted to 5.8 or less. At this time, the temperature of the concentrated nitric acid is preferably lower than 10 °C, more preferably lower than 9 °C, and even more preferably lower than 8 °C. When the concentrated nitric acid has a high temperature, this results in a high etching rate and may cause penetration through or loss of the cladding layer. Moreover, the concentration of the concentrated nitric acid is preferably 60 wt % or more, more preferably 61 wt % or more, and even more preferably 62 wt % or more. When the concentration of the concentrated nitric acid is less than 60 wt %, this may result in inadequate rough surface formation. The surface roughening treatment is preferably performed such that the light extraction surface 31A of the second conductivity type cladding layer 31 has an arithmetic mean height (Sa) of 0.60 μm or less and a skewness (Ssk) of 0.30 or more, and is more preferably performed such that Sa is 0.55 μm or less and Ssk is 0.40 or more. In addition, a step of forming a mesa structure and a step of cutting a section removed through the mesa to perform segmentation may be included after the surface roughening treatment step. Moreover, in a situation other than when the surface roughening treatment step is to be performed with the upper surface electrode exposed, a step of masking an upper surface electrode region or a section that is not to undergo surface roughening using a resist or the like can be included prior to immersion in the etchant. In this manner, a semiconductor light-emitting element 200 illustrated in FIG. 7 can be produced.

### <<Protective Film Formation Step>>

Although not illustrated, the semiconductor light-emitting element may be obtained by providing a protective film on the surface, inclusive of the light extraction surface 31A of the second conductivity type cladding layer 31, after the surface roughening treatment step. The protective film can be formed by a commonly known technique such as plasma CVD or sputtering. SiO₂, SiN, ITO, AlN, or the like can be used as the protective film. The protective film has an effect of increasing light extraction by suppressing a refractive index difference between the n-type cladding layer 31 and air and also has an effect of improving energized life characteristics of the semiconductor light-emitting element. In the case of the second conductivity type cladding layer 31 that has undergone the surface roughening treatment step according to the present disclosure, it is possible to form the protective film without the formations of sections where the protective film and the second conductivity type cladding layer 31 are not in contact (i.e., voids) because hollowing does not occur at a boundary between a region where the surface of the second conductivity type cladding layer 31 is subjected to surface roughening and a region that does not undergo surface roughening. Note that a protective film protecting a side surface of the semiconductor laminate 30 may be further provided.

The present embodiment is taken to be an embodiment in which an n-type InP substrate is used as the growth substrate 10 for convenience of description, and thus the n- and p-types of layers formed on the growth substrate 10 are as described above, but it should of course be recognized that the conductivity types (n-type/p-type) of layers can be reversed.

Although a present embodiment has been described above, embodiments are not limited to this embodiment, and various modifications can be made within the scope of the present disclosure using commonly known techniques. For example, in a situation in which a bonding method is not adopted, when an n-type substrate is used as the growth substrate 10, for example, the first conductivity type cladding layer may be changed to an n-type and the second conductivity type cladding layer 31 may be changed to a p-type, the first conductivity type cladding layer 37, the light-emitting layer 35, and the second conductivity type cladding layer 31 may be formed in this order as the semiconductor laminate 30 on the growth substrate 10, the contact layer 41 may be formed on the second conductivity type cladding layer 31, the ohmic metal sections 43 may subsequently be formed on the surface of the contact layer 41 as illustrated in Step 40 and Step 50 in FIG. 3, and an upper surface of the second conductivity type cladding layer (first conductivity type cladding layer 37 and cap layer 39 in FIG. 3) that has been exposed through subsequent removal of part of the contact layer 41 may be subjected to the surface roughening treatment step as a light extraction surface 31A. Moreover, the rear surface electrode 91 may be formed at a rear surface of the growth substrate 10. In this case, the ohmic metal sections 43 fulfill the role of an upper surface electrode. In a situation in which a bonding method in not adopted, the etching stop layer 20 may or may not be included. Also note that although the side surface of the semiconductor laminate 30 that is illustrated is drawn perpendicularly, the side surface of the semiconductor laminate 30 may be inclined as a result of mesa etching in the step of forming a mesa structure. Although the following provides a more detailed description of the present disclosure through examples, the present disclosure is not in any way limited by the following examples.

### EXAMPLES

Semiconductor light-emitting elements according to Examples 1 to 5 and Comparative Examples 1 to 6 described below were produced by a bonding method with a target central emission wavelength of 1,000 nm to 1,900 nm. Although the following provides a more detailed description of the present disclosure through examples, the present disclosure is not in any way limited by the following examples.

### Example 1

The thickness and dopant concentration of each constituent of a semiconductor light-emitting element according to Example 1 are shown in Table 1 for a state after growth on a growth substrate, but before bonding to a supporting substrate.

TABLE 1

| | | | | Dopant | | |
|---|---|---|---|---|---|---|
| | | | Thickness | concentration | | |
| Semiconductor layer | | Composition | nm | cm⁻³ | | |
| p-Type contact layer | | p-InGaAs | 100 | 1.5 × 10¹⁹ | | |
| p-Type cap layer | | p-InGaAsP | 50 | 5.0 × 10¹⁸ | | |
| p-Type cladding layer | | p-InP | 2400 | 7.0 × 10¹⁷ | | |
| Second spacer layer | | i-InP | 320 | — | | |
| Light-emitting | Barrier layer | i-InGaAlAs | 8 | — | | |
| layer | Well layer | i-InGaAlAs | 10 | — | | |
| (MQW active | Barrier layer | i-InGaAlAs | 8 | — | | |
| layer) | Well layer | i-InGaAlAs | 10 | — | | |
| | : | | | | | |
| | : | | | | {close oversize brace} | (Barrier layer + well layer) × 10 layers |
| | Barrier layer | i-InGaAlAs | 8 | — | | |
| | Well layer | i-InGaAlAs | 10 | — | | |
| | Barrier layer | i-InGaAlAs | 8 | — | | |

| | | | |
|---|---|---|---|
| First spacer layer | i-InGaAlAs | 100 | — |
| n-Type cladding layer | n-InGaAlAs | 4800 | 5.0 × 10¹⁷ |
| Etching stop layer | n-InGaAs | 20 | 5.0 × 10¹⁷ |
| Initial growth layer | n-InP | 100 | 5.0 × 10¹⁷ |
| Growth substrate | n-InP | — | 2.0 × 10¹⁸ |

The semiconductor light-emitting element according to Example 1 was produced according to the flowchart for a method of producing a bonding-type semiconductor light-emitting element that is illustrated in FIGS. 2 to 4. Specifically, the semiconductor light-emitting element was produced as follows. First, on a (100) face of an n-type InP substrate, an n-type InP initial growth layer (100 nm), an n-type In_{0.57}Ga_{0.43}As etching stop layer (20 nm), an n-type In_{0.52}Ga_{0.18}Al_{0.30}As (i.e., Al composition ratio 30%) cladding layer (thickness: 4,800 nm; dopant concentration: 5.0×10¹⁷ atoms/cm³), an i-type In_{0.52}Ga_{0.18}Al_{0.30}As spacer layer (thickness: 100 nm), a light-emitting layer (188 nm in total) having a quantum well structure with a light-emission wavelength of 1,490 nm, an i-type InP spacer layer (thickness: 320 nm), a p-type InP cladding layer (2,400 nm; dopant concentration: 7.0×10¹⁷ atoms/cm³), a p-type In_{0.8}Ga_{0.20}As_{0.5}P_{0.5} cap layer (thickness: 50 nm; dopant concentration: 5.0×10¹⁸ atoms/cm³), and a p-type In_{0.57}Ga_{0.43} As contact layer (thickness: 100 nm; dopant concentration: 1.5×10¹⁹ atoms/cm³) were sequentially formed using an MOCVD apparatus. Note that in formation of the light-emitting layer having a quantum well structure, an In_{0.526}Ga_{0.398}Al_{0.076}As barrier layer (thickness: 8 nm) was formed, and then an In_{0.567}Ga_{0.352}Al_{0.081}As well layer (thickness: 10 nm) and an In_{0.526}Ga_{0.398}Al_{0.076}As barrier layer (thickness: 8 nm) were stacked alternately for 10 pairs.

p-Type ohmic electrode sections (Au/AuZn/Au; total thickness: 530 nm) were formed in dispersed island shapes on the p-type In_{0.57}Ga_{0.43}As contact layer to form contact sections. In this pattern formation, a resist pattern was formed, an ohmic electrode was then vapor deposited, and lift-off of the resist pattern was performed to form the pattern. Upon observation of the upper surface of a semiconductor laminate of a wafer using an optical microscope in this state, the contact area ratio of the p-type ohmic electrode sections with the semiconductor laminate was 0.95%. Heat treatment was performed at 300 °C for 1 minute in order to make ohmic contact.

Next, a resist mask was formed on the ohmic electrode sections, and the p-type In_{0.57}Ga_{0.43}As contact layer was removed through tartaric acid-hydrogen peroxide wet etching at locations other than locations where the ohmic electrode sections had been formed. After resist removal, a dielectric layer (thickness: 700 nm) formed of SiO₂ was formed over the entire surface of the p-type In_{0.80}Ga_{0.20}As_{0.50}P_{0.50} cap layer by plasma CVD. A window pattern having a shape provided with a width of 10 μm in a region above the p-type ohmic electrode sections was formed by a resist, and the dielectric layer was removed by wet etching using BHF at the p-type ohmic electrode sections and the peripheries thereof to expose the p-type In_{0.80}Ga_{0.20}As_{0.50}P_{0.50} cap layer. At this time, the height H₁ (700 nm) of the dielectric layer on the p-type In_{0.80}Ga_{0.20}As_{0.50}P_{0.50} cap layer is 30 nm higher than the height H₂ (670 nm) of a contact layer formed of the p-type contact layer (thickness: 120 nm) and the p-type ohmic electrode sections (thickness: 530 nm). Note that upon observation of the upper surface of a semiconductor laminate of a wafer using an optical microscope in this state, the contact area ratio of the dielectric layer (SiO₂) was 93%.

Next, a metal reflective layer (Ti/Au/Pt/Au) was formed over the entire surface of the p-type In_{0.80}Ga_{0.20}As_{0.50}P_{0.50} cap layer and the dielectric layer by vapor deposition. The thicknesses of metal layers in the metal reflective layer are, in order, 2 nm of Ti, 650 nm of Au, 10 nm of Pt, and 900 nm of Au.

Meanwhile, a metal bonding layer (Ti/Pt/Au) was formed on a conductive Si substrate (thickness: 300 μm) serving as a supporting substrate. The thicknesses of metal layers in the metal bonding layer are, in order, 650 nm of Ti, 10 nm of Pt, and 900 nm of Au.

The metal reflective layer and the metal bonding layer were arranged in opposition and were hot compression bonded at 315 °C. The InP substrate was then removed by wet etching using dilute hydrochloric acid.

Next, upper surface ohmic electrode formation was performed. An upper surface electrode pattern was formed by forming a resist pattern at locations other than where the upper surface electrode was to be formed, vapor depositing an n-type electrode (Au (thickness: 10 nm)/Ge (thickness: 33 nm)/Au (thickness: 57 nm)/Ni (thickness: 34 nm)/Au (thickness: 800 nm)/Ti (thickness: 100 nm)/Au (thickness: 1,000 nm)), and performing lift-off of the resist pattern. A pad section (Ti (thickness: 150 nm)/Pt (thickness: 100 nm)/Au (thickness: 2,500 nm)) was then further formed on a circular section at the center of the n-type electrode to yield an upper surface electrode pattern such as illustrated in FIG. 8.

The etching stop layer was removed through etching using a tartaric acid-hydrogen peroxide etchant.

Next, the light extraction surface of the n-type cladding layer was subjected to surface roughening treatment. First, a resist pattern was formed with respect to regions that were not to undergo surface roughening (subsequently described planned mesa etching position at upper surface of n-type cladding layer and top and periphery of upper surface electrode). The resist is a film that blocks etching. A region where this resist pattern is not formed is a region where surface roughening is to be performed. Thereafter, immersion in concentrated nitric acid (61 wt %) for semiconductors that had been cooled to 8 °C was performed with a standing time of 5 seconds. The product was removed straight away thereafter and was subjected to 60 seconds of running water washing through shaking in overflowing pure water, 80 seconds of alkali washing through shaking in ammonia water, 60 seconds of running water washing through shaking in overflowing pure water once again, and then blow drying. The resist pattern was subsequently removed.

Next, a dicing line was formed by mesa etching. A resist pattern was formed with respect to regions other than the dicing line, and semiconductor laminate above the dicing line was removed by dry etching. Next, SiN (thickness: 190 nm) as a protective film was formed over the entire surface by plasma CVD such as to cover the surface, inclusive of an inclined side surface (mesa side surface) of the semiconductor laminate that had been formed through dry etching and the previously described light extraction surface. The protective film (SiN) on the pad electrode was partially removed in order to expose part of the pad electrode surface necessary for wire bonding. After the light-emitting layer side had been protected using a resist, a grinder was used to perform grinding until the thickness of the supporting substrate (Si substrate) was 150 μm. Next, a rear surface electrode (Ti (thickness: 10 nm)/Pt (thickness: 50 nm)/Au (thickness: 200 nm)) was formed at a rear surface side, corresponding to a ground surface of the Si substrate, and then chip segmentation was performed by dicing to produce a semiconductor light-emitting element according to Example 1. Note that the chip size is 250 μm×250 μm.

### Examples 2 to 5 and Comparative Examples 1 to 6

In the following examples and comparative examples, semiconductor light-emitting elements in which the Al composition ratio of the n-type cladding layer formed of InGaAlAs was appropriately changed in a range of 48% to 0% and semiconductor light-emitting elements in which the composition of the n-type cladding layer was changed to InP or GaAs were produced.

### Example 2

A semiconductor light-emitting element according to Example 2 was obtained in the same way as in Example 1 with the exception that the composition of the n-type cladding layer was changed from In_{0.52}Ga_{0.18}Al_{0.30}As to In_{0.52}Ga_{0.23}Al_{0.25}As (i.e., the Al composition ratio was changed to 25%).

### Example 3

A semiconductor light-emitting element according to Example 3 was obtained in the same way as in Example 1 with the exception that the composition of the n-type cladding layer was changed from In_{0.52}Ga_{0.18}Al_{0.30}As to In_{0.52}Ga_{0.28}Al_{0.20}As (i.e., the Al composition ratio was changed to 20%).

### Example 4

A semiconductor light-emitting element according to Example 4 was obtained in the same way as in Example 1 with the exception that the composition of the n-type cladding layer was changed from In_{0.52}Ga_{0.18}Al_{0.30}As to In_{0.52}Ga_{0.33}Al_{0.15}As (i.e., the Al composition ratio was changed to 15%).

### Example 5

A semiconductor light-emitting element according to Example 5 was obtained in the same way as in Example 1 with the exception that the composition of the n-type cladding layer was changed from In_{0.52}Ga_{0.18}Al_{0.30}As to In_{0.52}Ga_{0.38}Al_{0.10}As (i.e., the Al composition ratio was changed to 10%).

### Comparative Example 1

A semiconductor light-emitting element according to Comparative Example 1 was obtained in the same way as in Example 1 with the exception that the composition of the n-type cladding layer was changed from In_{0.52}Ga_{0.18}Al_{0.30}As to In_{0.52}Al_{0.48}As (i.e., the Al composition ratio was changed to 48%).

### Comparative Example 2

A semiconductor light-emitting element according to Comparative Example 2 was obtained in the same way as in Example 1 with the exception that the composition of the n-type cladding layer was changed from In_{0.52}Ga_{0.18}Al_{0.30}As to In_{0.52}Ga_{0.13}Al_{0.35}As (i.e., the Al composition ratio was changed to 35%).

### Comparative Example 3

A semiconductor light-emitting element according to Comparative Example 3 was obtained in the same way as in Example 1 with the exception that the composition of the n-type cladding layer was changed from In_{0.52}Ga_{0.18}Al_{0.30}As to In_{0.52}Ga_{0.43}Al_{0.05}As (i.e., the Al composition ratio was changed to 5%).

### Comparative Example 4

A semiconductor light-emitting element according to Comparative Example 4 was obtained in the same way as in Example 1 with the exception that the composition of the n-type cladding layer was changed from In_{0.52}Ga_{0.18}Al_{0.30}As to In_{0.52}Ga_{0.43} As (i.e., the Al composition ratio was changed to 0%).

### Comparative Example 5

A semiconductor light-emitting element according to Comparative Example 5 was obtained in the same way as in Example 1 with the exception that the composition of the n-type cladding layer was changed from In_{0.52}Ga_{0.18}Al_{0.30}As to InP.

### Comparative Example 6

A semiconductor light-emitting element according to Comparative Example 6 was obtained in the same way as in Example 1 with the exception that the composition of the n-type cladding layer was changed from In_{0.52}Ga_{0.18}Al_{0.30} As to GaAs.

### (Evaluation of Light Emission Characteristics)

For each of the semiconductor light-emitting elements according to Examples 1 to 5 and Comparative Examples 1 to 6, the forward voltage Vf (V) and the light emission output Po (mW) according to an integrating sphere were measured for when forward currents If (mA) of 30 mA and 36 mA were passed using a constant current/voltage power supply. The central emission wavelength λp (nm) and the full width at half maximum (FWHM; units: nm) according to a spectral analyzer (AQ6374 produced by Yokogawa Test & Measurement Corporation) were also measured. Note that in these measurements, an average value of measurement results for three samples was determined. Next, the light emission output was divided by the injected power at that time to calculate Po/(Vf·If), the value of which was taken as an index of light emission output relative to injected power. In addition, an evaluation was made in each example or comparative example for the rate of increase of light emission output relative to a comparative product that was produced by completely the same process with the exception that surface roughening of the second conductivity type cladding layer was not performed. The various measurement results and calculation results are shown in Table 2. A rate of increase of Po of 120% or more was evaluated as “A”, a rate of increase of Po of 110% or more was evaluated as “B”, and a rate of increase of Po of less than 110% was evaluated as “C”. Although not shown in Table 2, the central emission wavelength was within a range of 1,490 nm±10 nm in each example or comparative example.

TABLE 2

| | | | | | | | | Po | SEM cross- |
|---|---|---|---|---|---|---|---|---|---|
| | Composition ratios | | | | Sa | | | rate of | section |
| | Composition | In (%) | Ga (%) | Al (%) | (μm) | Sdr | Ssk | increase* | hollowing |
| Comparative | InAlAs | 52 | 0 | 48 | 0.69 | 6.78 | 0.24 | A | Yes |
| Example 1 | | | | | | | | | |
| Comparative | InGaAlAs | 52 | 13 | 35 | 0.63 | 5.91 | 0.26 | A | Yes |
| Example 2 | | | | | | | | | |
| Example 1 | InGaAlAs | 52 | 18 | 30 | 0.59 | 5.46 | 0.34 | A | No |
| Example 2 | InGaAlAs | 52 | 23 | 25 | 0.55 | 5.24 | 0.43 | A | No |
| Example 3 | InGaAlAs | 52 | 28 | 20 | 0.52 | 4.81 | 0.50 | A | No |
| Example 4 | InGaAlAs | 52 | 33 | 15 | 0.50 | 4.44 | 0.61 | A | No |
| Example 5 | InGaAlAs | 52 | 38 | 10 | 0.63 | 4.86 | 0.47 | A | No |
| Comparative | InGaAlAs | 52 | 43 | 5 | 0.63 | 4.39 | 0.54 | B | No |
| Example 3 | | | | | | | | | |
| Comparative | InGaAs | 52 | 48 | 0 | 0.55 | 3.33 | 0.65 | C | No |
| Example 4 | | | | | | | | | |
| Comparative | n-InP | 100 | 0 | 0 | — | — | — | C | — |
| Example 5 | | | | | | | | | |
| Comparative | n-GaAs | 0 | 100 | 0 | 0.11 | 0.11 | 1.66 | C | No |
| Example 6 | | | | | | | | | |

*Po rate of increase A: ≥120%, B: ≥110%, C: <110%

### (Measurement of Roughness of Light Extraction Surface)

As previously described, a profile analysis laser microscope (VK-X1000/1100 produced by Keyence Corporation) was used to perform measurement of the rough surface shape of a surface of an n-type cladding layer (second conductivity type cladding layer) in a post-surface roughening treatment chip (after dicing). The lens magnification was set as x50, and the number of pixels was set as 2048×1536.

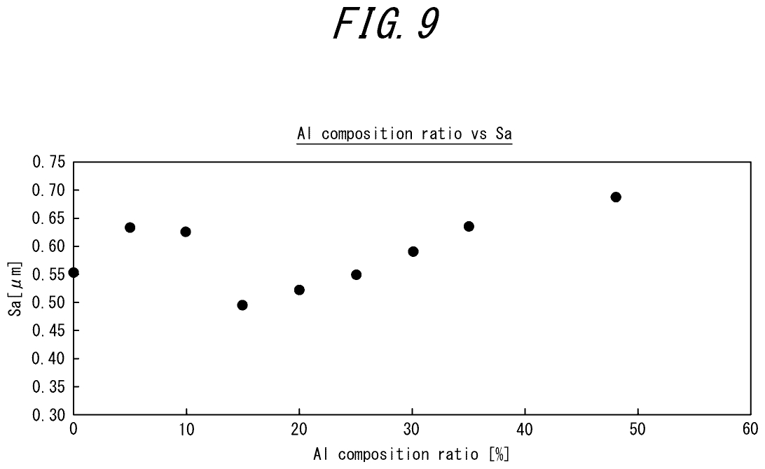

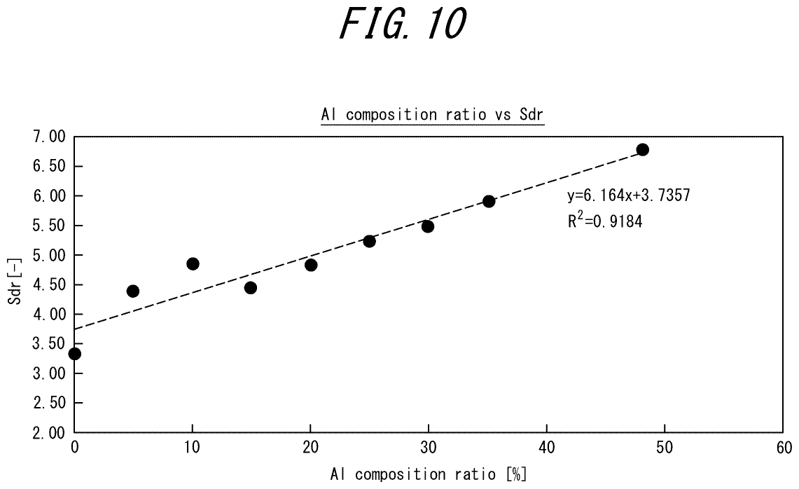

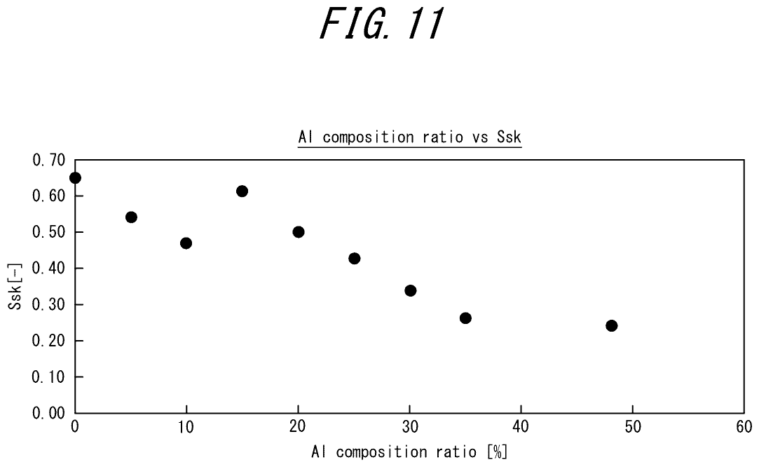

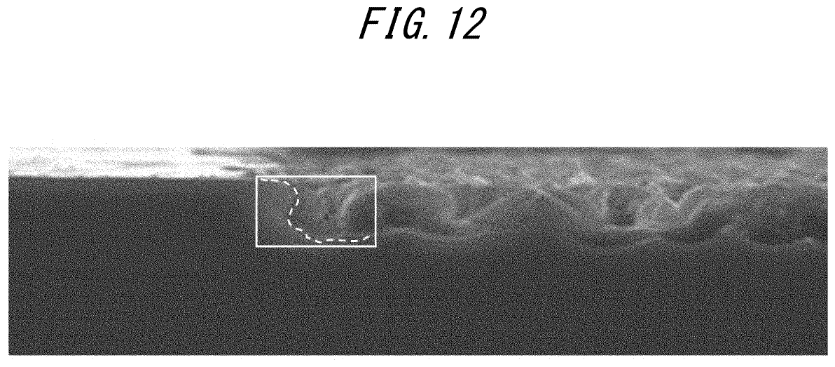

During data measurement, surface roughness parameters (Sa, Sz, Spc, Sdr, Ssk, etc.) are automatically calculated based on ISO 25178. Of these values, Sa, Sdr, and Ssk are shown above in Table 2, and their relationships with the Al composition ratio are illustrated in FIGS. 9 to 11. It can be seen from the graphs that the influence of surface roughening by etching increases with increasing Al composition ratio, and that particularly in the relationship with Sdr, there is a clear first order correlation. Note that surface roughness parameters for Comparative Example 5 are recorded as “-” in Table 2 because InP is not etched.

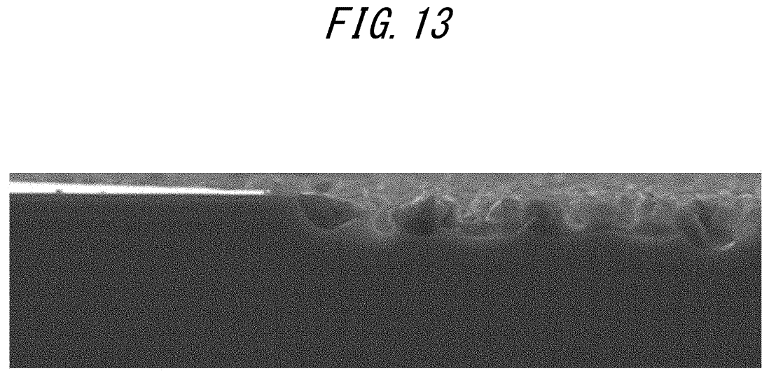

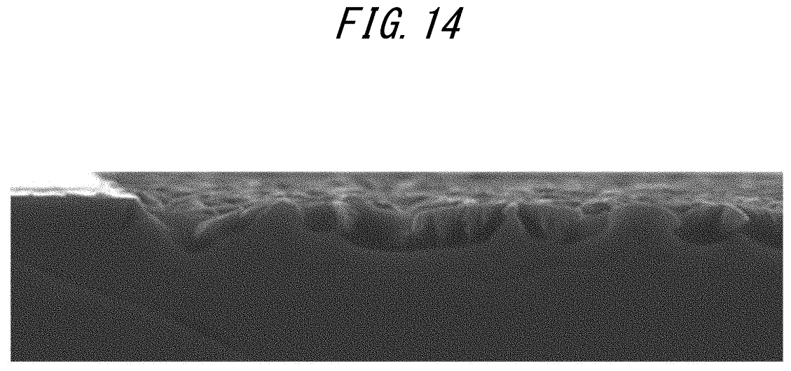

FIGS. 12 to 14 illustrate electron micrographs around the surface of an n-type cladding layer after surface roughening treatment in a cross-section obtained through cleaving such as to pass through an n-side electrode formation region of a light-emitting element in Comparative Example 1, Example 1, and Comparative Example 4, which are taken as representative examples. As illustrated in FIG. 13, the formation of a rough surface of sufficient roughness is observed at the surface of the second conductivity type cladding layer in Example 1, which satisfies the scope of the present disclosure.

On the other hand, in Comparative Example 1 in which there is a high Al composition ratio exceeding the scope of the present disclosure, the occurrence of hollowing was confirmed at a boundary between a region where a resist pattern was used such that surface roughening was not performed and a region where surface roughening was performed as illustrated in FIG. 12 (note that the frame line and dashed line were added by the applicant), whereas hollowing such as illustrated in FIG. 12 was not observed in Example 1 and Comparative Example 4.

### INDUSTRIAL APPLICABILITY

According to the present disclosure, it is possible to provide a semiconductor light-emitting element that has good light emission output relative to injected power compared to conventional light-emitting elements and in which a protective film can be formed without the formation of voids, and also to provide a method of producing this semiconductor light-emitting element.

### REFERENCE SIGNS LIST

10 growth substrate
20 etching stop layer
30 semiconductor laminate
31 second conductivity type cladding layer
31A light extraction surface
35 light-emitting layer
35W well layer
35B barrier layer
37 first conductivity type cladding layer
39 cap layer
40 contact section
41 contact layer
41A contact region
43 ohmic metal section
50 dielectric layer
60 metal reflective layer
70 metal bonding layer
80 supporting substrate
100 semiconductor light-emitting element
91 rear surface electrode
93 upper surface electrode

1. A semiconductor light-emitting element comprising a first conductivity type cladding layer, a light-emitting layer, and a second conductivity type cladding layer in stated order with the second conductivity type cladding layer as a light extraction side, wherein
the light-emitting layer is a III-V compound semiconductor that includes one type or two or more types among Al, Ga, and In as group III elements, includes one type or two or more types among As, Sb, and P as group V elements, and has a central emission wavelength of 1,000 nm to 1,900 nm,
the second conductivity type cladding layer has a composition of InₓGa_{y}Al_{z}As, where 0.49≤x≤0.55, 0.10≤z<0.35, and x+y+z=1, and
the second conductivity type cladding layer has a light extraction surface with a developed interfacial area ratio (Sdr) of 4.0 or more.

2. The semiconductor light-emitting element according to claim 1, wherein the second conductivity type cladding layer has an Al composition ratio z of 0.15≤z≤0.30.

3. The semiconductor light-emitting element according to claim 1, wherein the light extraction surface of the second conductivity type cladding layer has an arithmetic mean height (Sa) of 0.60 μm or less and a skewness (Ssk) of 0.30 or more.

4. The semiconductor light-emitting element according to claim 1, wherein a band gap of the second conductivity type cladding layer is larger than a band gap of the light-emitting layer.

5. The semiconductor light-emitting element according to claim 1, wherein the second conductivity type cladding layer has a thickness of not less than 2 μm and not more than 10 μm.

6. The semiconductor light-emitting element according to claim 1, wherein the light-emitting layer has a quantum well-type structure in which an InGaAlAs well layer and an InGaAlAs barrier layer are stacked alternately.

7. The semiconductor light-emitting element according to claim 1, comprising an undoped spacer layer between the first conductivity type cladding layer and the light-emitting layer and between the light-emitting layer and the second conductivity type cladding layer.

8. The semiconductor light-emitting element according to claim 1, comprising a supporting substrate, the first conductivity type cladding layer, the light-emitting layer, and the second conductivity type cladding layer in stated order and comprising a metal reflective layer between the supporting substrate and the first conductivity type cladding layer, wherein
a dielectric layer and a contact section that are disposed alongside each other are further included between the metal reflective layer and the first conductivity type cladding layer.

9. A method of producing a semiconductor light-emitting element having a second conductivity type cladding layer as a light extraction side, comprising:
a semiconductor laminate formation step of sequentially forming a first conductivity type cladding layer, a light-emitting layer, and the second conductivity type cladding layer; and
a surface roughening treatment step of immersing the second conductivity type cladding layer in concentrated nitric acid to perform surface roughening and thereby adjust a developed interfacial area ratio (Sdr) of a light extraction surface of the second conductivity type cladding layer to 4.0 or more, wherein
the light-emitting layer is a III-V compound semiconductor that includes one type or two or more types among Al, Ga, and In as group III elements, includes one type or two or more types among As, Sb, and P as group V elements, and has a central emission wavelength of 1,000 nm to 1,900 nm, and
the second conductivity type cladding layer has a composition of InₓGa_{y}Al_{z}As, where 0.49≤x≤0.55, 0.10≤z<0.35, and x+y+z=1.

10. The method of producing a semiconductor light-emitting element according to claim 9, wherein the concentrated nitric acid in the surface roughening treatment step has a temperature of lower than 10 °C.

11. The method of producing a semiconductor light-emitting element according to claim 9, wherein the concentrated nitric acid in the surface roughening treatment step has a concentration of 60 wt % or more.

12. The method of producing a semiconductor light-emitting element according to claim 9, wherein the second conductivity type cladding layer has an Al composition ratio z of 0.15≤z≤0.30.

13. The method of producing a semiconductor light-emitting element according to claim 9, wherein surface roughening treatment is performed in the surface roughening treatment step such that the light extraction surface of the second conductivity type cladding layer has an arithmetic mean height (Sa) of 0.6 μm or less and a skewness (Ssk) of 0.3 or more.

14. The method of producing a semiconductor light-emitting element according to claim 9, further comprising, after the surface roughening treatment step, a step of forming a mesa structure and a step of cutting a section removed by a mesa to perform segmentation.

15. A method of producing a semiconductor light-emitting element comprising:
a semiconductor laminate formation step of sequentially forming an etching stop layer, a second conductivity type cladding layer, a light-emitting layer, and a first conductivity type cladding layer on a growth substrate;
a step of forming a dielectric layer and a contact section alongside each other on the first conductivity type cladding layer;
a metal reflective layer formation step of forming a metal reflective layer on the dielectric layer and the contact section;
a bonding step of bonding a supporting substrate differing from the growth substrate via the metal reflective layer;
a growth substrate removal step of removing the growth substrate to expose the etching stop layer;
a second conductivity type cladding layer exposure step of removing the etching stop layer to expose an upper surface of the second conductivity type cladding layer as a light extraction side; and
a surface roughening treatment step of, after the second conductivity type cladding layer exposure step, immersing the second conductivity type cladding layer in concentrated nitric acid to perform surface roughening and thereby adjust a developed interfacial area ratio (Sdr) of a light extraction surface of the second conductivity type cladding layer to 4.0 or more, wherein
the light-emitting layer is a III-V compound semiconductor that includes one type or two or more types among Al, Ga, and In as group III elements, includes one type or two or more types among As, Sb, and P as group V elements, and has a central emission wavelength of 1,000 nm to 1,900 nm, and
the second conductivity type cladding layer has a composition of InₓGa_{y}Al_{z}As, where 0.49≤x≤0.55, 0.10≤z<0.35, and x+y+z=1.
